(19) United States
(12) Patent Application Publication
(10) Pub. No.: US 2026/0109594 A1
(43) Pub. Date: Apr. 23, 2026

(54) ACOUSTIC RESONATING DEVICES AND ASSEMBLIES

(71) Applicant: University of Pittsburgh - Of the Commonwealth System of Higher Education, Pittsbugh, PA (US)

(72) Inventors: Sung Kwon Cho, Pittsburgh, PA (US); Wenbo Li, Pittsburgh, PA (US)

(21) Appl. No.: 19/363,002

(22) Filed: Oct. 20, 2025

Related U.S. Application Data
(60) Provisional application No. 63/710,881, filed on Oct. 23, 2024.

(51) Int. Cl. B81B 3/00

(52) U.S. Cl. CPC B81B 3/0027; B81B 2201/05; B81B 2203/019; B81B 2203/0315; B81B 2203/056

(57) ABSTRACT

A device includes a body. The body includes a cavity therein. A diaphragm separates the cavity from an environment surrounding the device to enclose a gas within the cavity. One or more extending members are attached to and extend outwardly from a surface of the diaphragm. The cavity resonates upon application of ultrasound energy thereto to cause movement in the diaphragm and the one or more extending members.

### CROSS-REFERENCE TO RELATED APPLICATIONS

This application claims benefit of U.S. Provisional Patent Application Ser. No. 63/710,881, filed Oct. 23, 2024, the disclosure of which is incorporated herein by reference.

### GOVERNMENTAL INTEREST

This invention was made with government support under grant number EB035724 awarded by the National Institutes of Health and grant number 2335000 awarded by the National Science Foundation. The government has certain rights in the invention.

### BACKGROUND

The following information is provided to assist the reader in understanding technologies disclosed below and the environment in which such technologies may typically be used. The terms used herein are not intended to be limited to any particular narrow interpretation unless clearly stated otherwise in this document. References set forth herein may facilitate understanding of the technologies or the background thereof. The disclosure of all references cited herein are incorporated by reference.

Microdevices or microrobots are known to maneuver in liquid environments. Such untethered, mobile or “swimming” robots (sometimes referred to herein as “microswimmers”) have, for example, been studied for potential use in biomedical applications including, for example, diagnosing diseases, transporting drugs, treating diseases locally, etc. Much research has thus been devoted in efforts to demonstrate microscale propulsion with various methods. Magnetic propulsion, chemical propulsion, bio-combined propulsion and acoustic propulsion have been studied. Among such mechanisms or methods of propulsion, acoustic propulsion holds unique advantages in that it is very inexpensive and can achieve relatively strong “swimming”speed at low actuation amplitude.

Typically, two actuation methods for acoustic propulsion are used in swimming microdevices: acoustic bubble propulsion and acoustic sharp edge propulsion. Under acoustic actuation, the liquid air interface on bubble is oscillated periodically. Because oscillation frequency is typically high, although the dimension of micro bubble is small, oscillatory Reynolds number is large enough to generate a net streaming from the bubble. The streaming results in a reactive force back on a microdevice, which propels motion of the microdevice. 2D and 3D navigations have been demonstrated with such microdevices. Speeds of such microdevices have, for example, been confirmed to be around 5 cm/s. However, acoustically-actuated microbubble devices usually experience short longevity under water (for example, exhibiting useful lives of approximately 5 minutes). In that regard, oscillating microbubbles relatively quickly dissolve in a liquid medium. While a narrower opening has been studied in an attempt to enhance longevity, longevity of microbubble-based microdevices remains a significant issue.

Many studies of microswimmers rely on acoustically oscillated mechanical systems, such as a glass plate, a microchannel or a water tank acoustically actuated by an ultrasound generator such as a piezo disk. Such devices introduce additional acoustic resonances into the system, and swimmer motion observed during use of such devices may be affected by such resonances. To simulate a system closer to real-world application of microswimmers in, for example, a human body, an acoustic beam may be used. The acoustic beam direction and swimming direction of the microswimmer should not interfere with each other. Acoustic bubbles are useful because no matter what orientation the acoustic beam originates, acoustic bubbles always propel in the direction opposite of open liquid-air interface.

As described above, another propulsion method used in microswimmers is sharp-edge propulsion in which a sharp edge is acoustically oscillated. Sharp edges were first observed to provide strong streaming in microfluidic systems. Fluid oscillation via sharp edge oscillation was observed to generate strong streaming force. The fluid oscillation direction is required to be perpendicular to sharp edge orientation. Relative motion of the sharp edge and the fluid causes a centrifugal force to be experienced by the fluid which forces it away from the sharp edge resulting in a reactive force. Multiple studies have been conducted to develop sharp-edge microswimmers with possible steering capability. However, all sharp-edge microswimmers rely on materials of the sharp edge being extremely soft (that is, the Young modulus E should be down to approximately 100 kPa, or approximately 200 kPa). Even regular polydimethylsiloxane or PDMS (having an E or approximately 1 MPa) is not soft enough for the sharp edge to generate noticeable propulsion.

Thus, while acoustically oscillating microbubbles can generate streaming flows that, in turn, generate a reactionary force (propulsion), microbubble-based devices suffer from poor longevity. While oscillating sharp edges can also generate streaming flows and thus propulsion, such devices suffer from relatively low tunability for frequency, high susceptibility to acoustic wave direction, and critical requirement for ultra flexibility in the sharp edge material (Young modulus E should be down to ˜100 kPa).

It is desirable to develop resonating microdevices capable of inducing streaming flow in liquid environments that reduce or eliminate problems associates with current resonating microdevices.

### SUMMARY

A device includes a body. The body includes a cavity (that is, a gas-filled volume) therein. A diaphragm separates the cavity from an environment surrounding the device to enclose the gas within the cavity. One or more extending members are attached to and extend outwardly from a surface of the diaphragm. The cavity resonates upon application of ultrasound energy thereto to cause movement in the diaphragm and the one or more extending members. In a number of embodiments, the device includes a plurality of the extending members (for example, two of the extending members). The dimensions of the cavity may be selected to control a resonance frequency of the cavity. In a number of embodiments, the body has no dimension greater than 5 mm, no greater than 1 mm, no greater than 500 μm, no greater than 300 μm, or no greater than 270 nm. In a number of embodiments, each of the extending members has a height of no greater than 270 μm. In a number of embodiments, each of the extending members has a height in the range of approximately 80 μm to approximately 130 μm.

An assembly includes a plurality of devices which are attached. Each of the devices includes a body. The body has a cavity therein. A diaphragm separates the cavity from an environment surrounding the device to enclose a gas within the cavity. One or more extending members are attached to and extend outwardly from a surface of the diaphragm. The cavity resonates upon application of ultrasound energy thereto to cause movement in the diaphragm and in the one or more extending members. Each of two or more of the plurality of devices are attached in different orientations (that is, different orientations of the one or more extending members) and have different resonance frequencies (of the cavities thereof) to achieve controlled steered motion via streaming flow and propulsion in a liquid in which the assembly is immersed via control of applied ultrasound energy (that is, control of at least one of frequency and amplitude of applied ultrasound energy).

Each of the plurality of devices comprises a plurality of the extending members. In a number of embodiments, each of the plurality of devices includes two of the extending members. The dimensions of the cavity of each of the two or more devices may be selected to control a resonance frequency of the cavity. In a number of embodiments, the body of each of the plurality of devices has no dimension greater than 5 mm, no greater than 1 mm, no greater than 500 μm, no greater than 300 μm, or no greater than 270 nm. In a number of embodiments, each of the extending members of each of the plurality of devices has a height of no greater than 270 μm. In a number of embodiments, each of the extending members has a height in the range of approximately 80 μm to approximately 130 μm.

A method of generating streaming comprising providing one or more of the devices hereof, immersing the one or more devices in a liquid, and applying ultrasound energy to cause resonance in the cavity of the one or more devices. Generating streaming may, for example, be used to provide motion to the one or more of the devices or to a substrate to which the one or more devices are attached. In a number of embodiments, an ultrasound energy generator is acoustically coupled to the liquid to apply the ultrasound energy.

A method of generating controlled motion of an assembly hereof which is immersed in a liquid, includes applying ultrasound energy to cause resonance in the cavity of at least one of the one or more devices by applying the ultrasound energy at one or more of the different resonance frequencies, which is a resonance frequency for the at least one of the one or more devices, and at a selected amplitude to achieve controlled motion of the assembly in the liquid. In a number of embodiments, an ultrasound energy generator is acoustically coupled to the liquid to apply the ultrasound energy.

A system includes a plurality of devices attached to a surface. Each of the plurality of devices includes a body. The body of each of the plurality of devices has a cavity therein. A diaphragm separates the cavity from an environment surrounding the device to enclose a gas within the cavity. Each of the plurality of devices includes one or more extending members attached to and extending outwardly from a surface of the diaphragm. The cavity resonating upon application of ultrasound energy thereto to cause movement in the diaphragm and the one or more extending members to generate microstreaming in a liquid in which the system is immersed.

Each of the plurality of devices may include a plurality of the extending members. Each of the plurality of devices may, for example, include two of the extending members. The dimensions of the cavity of each of the plurality of devices may be selected to control a resonance frequency of the cavity of the device.

The present devices, systems, and methods, along with the attributes and attendant advantages thereof, will best be appreciated and understood in view of the following detailed description taken in conjunction with the accompanying drawings.

### BRIEF DESCRIPTION OF THE DRAWINGS

FIG. 1A illustrates a front view of an embodiment of a device or microdevice hereof.

FIG. 1B illustrates a side view of the microdevice of FIG. 1A.

FIG. 1C illustrates a top view of the microdevice of FIG. 1A.

FIG. 1D illustrates a cross-sectional view of the microdevice of FIG. 1A along section A-A as illustrated in FIG. 1C.

FIG. 1E illustrates a top isometric view of the device of FIG. 1A.

FIG. 1F illustrates an isometric cutaway view of the device of FIG. 1A.

FIG. 1G illustrates another isometric cutaway view of the device of FIG. 1A.

FIG. 1H illustrates another isometric cutaway view of the device of FIG. 1A.

FIG. 2A illustrates a perspective view of a microdevice of FIG. 1A wherein applied ultrasound (US) resonates in the cavity of the device, oscillates the cavity diaphragm (arrow D), generates large movements (arrows F) in both fins of the device, and thereby generates streaming flow in the liquid and strong propulsion.

FIG. 2B illustrates an isometric view of a representative experimental setup used to demonstrate two-dimensional or 2D, steered navigations in a microchannel for a microdevice assembly hereof.

FIG. 2C illustrates a top view of the experimental setup of FIG. 2B illustrating a microdevice assembly hereof including two of the microdevices of FIG. 1A having different resonances which are combined, attached or integrated in different orientations to from a microswimming assembly or system to achieve two-dimensional or 2D steered propulsion within a T-shaped microchannel formed in a substrate.

FIG. 2D illustrates an enlarged view of the microdevice assembly within the T-shaped microchannel, wherein arrows Ta and Tb illustrate the thrust force generated by each microdevice of the microdevice assembly in the illustrated orientation thereof.

FIG. 2E illustrates an enlarged isometric view of the microdevice assembly within the microchannel.

FIG. 3A illustrates photos demonstrating that a microdevice as illustrated in FIG. 1A, when anchored on a substrate generates strong streaming flows (wherein microparticles are seeded for flow visualization).

FIG. 3B illustrates high-speed, sequential images of an extending member or fin of a microdevice as illustrated in FIG. 1A, demonstrating undulation observed on the 390 μm length extending member or fin.

FIG. 3C illustrates photographs demonstrating propulsion of a microdevice of FIG. 1A over time.

FIG. 3D illustrates “swimming” speed vs. applied voltage to an ultrasound actuator (demonstrating a quadratic relation) at 30 kHz.

FIG. 4A illustrates a photograph of an embodiment of an experimental setup for measurement of propulsion force using a cantilever beam wherein a 70 μm deflection in the cantilever beam is estimated to be 5 μN propulsion force deflection through ANSYS® simulation.

FIG. 4B illustrates a photograph of an embodiment of the experimental setup of FIG. 4A for measurement of propulsion force using a cantilever beam wherein a 210 μm deflection in the cantilever beam is estimated to be 20 μN propulsion force deflection through ANSYS® simulation.

FIG. 4C illustrates schematically a drawing of the experimental setup of FIG. 4A, wherein the cantilever beam was 20 μm thick, 200 μm wide, and 500 μm long.

FIG. 4D illustrates the ANSYS simulation of the deflection results used in FIG. 4A.

FIG. 4E illustrates a graph of force as a function of voltage.

FIG. 4F illustrates schematically an experimental setup of a study on the influence of incident acoustic beam direction on performance of devices hereof.

FIG. 4G illustrates beam deflection resulting from devices hereof in four different directions.

FIG. 4H illustrates Table 1 which sets forth beam deflections, displacement and force for the four different directions of the studies of FIG. 4G.

FIG. 5A illustrates the dependance of swimming speed on extending member or fin length for lengths of 0, 45, 90, and 135 μm in frequency domain, wherein the 90 μm length shows fastest swimming speed.

FIG. 5B illustrates the effect of cavity height on swimming speed in frequency domain, wherein 28 kHz & 37 kHz were chosen for 2D steered propulsion in a microchannel (FIGS. 7A and 7B).

FIG. 6A illustrates four different microdevice designs for comparison in swimming speed and longevity, wherein: panel 1 is a microdevice with an air bubble trapped in cavity; panel 2 is a device with a diaphragm and without extending members or fins; panel 3 is the device of FIG. 1A; and panel 4 is a device with no cavity and with a single extending member or fin.

FIG. 6B illustrates that the device of FIG. 1A has high longevity as well as highest swimming speed, the bubble device shows high swimming speed but the bubble disappears shortly by dissolution, the device with an extending member or fin and with no cavity does not generate noticeable propulsion.

FIG. 7A illustrates photographs demonstrating steering of an assembly as illustrated in FIG. 2B, including two devices of FIG. 1A which are connected with different orientation, wherein the two devices have different cavity heights (170 and 110 μm) in microchannel, and wherein the acoustic input of 28 kHz activates only microdevice 1 resulting in a straight path for the assembly.

FIG. 7B illustrates photographs demonstrating steering of the assembly of FIG. 7A, wherein the acoustic input of 37 kHz at the channel junction activates only microdevice 2 and makes the assembly turn left.

FIG. 8 illustrates an embodiment of a microswimming system or assembly hereof including multiple integrated devices of FIG. 1A to achieve 3D steered propulsion.

FIG. 9 illustrates schematically an embodiment of a system hereof including a surface or substrate upon which a plurality of devices hereof are immobilized to induce microstreaming.

### DETAILED DESCRIPTION

It will be readily understood that the components of the embodiments, as generally described and illustrated in the figures herein, may be arranged and designed in a wide variety of different configurations in addition to the described representative embodiments. Thus, the following more detailed description of the representative embodiments, as illustrated in the figures, is not intended to limit the scope of the embodiments, as claimed, but is merely illustrative of representative embodiments.

Reference throughout this specification to “one embodiment” or “an embodiment” (or the like) means that a particular feature, structure, or characteristic described in connection with the embodiment is included in at least one embodiment. Thus, the appearance of the phrases “in one embodiment” or “in an embodiment” or the like in various places throughout this specification are not necessarily all referring to the same embodiment.

Furthermore, described features, structures, or characteristics may be combined in any suitable manner in one or more embodiments. In the following description, numerous specific details are provided to give a thorough understanding of embodiments. One skilled in the relevant art will recognize, however, that the various embodiments can be practiced without one or more of the specific details, or with other methods, components, materials, et cetera. In other instances, well known structures, materials, or operations are not shown or described in detail to avoid obfuscation.

As used herein and in the appended claims, the singular forms “a,” “an,” and “the” include plural references unless the context clearly dictates otherwise. Thus, for example, reference to “an extending member” includes a plurality of such extending members and equivalents thereof known to those skilled in the art, and so forth, and reference to “the extending member” is a reference to one or more such extending members and equivalents thereof known to those skilled in the art, and so forth. Recitation of ranges of values herein are merely intended to serve as a shorthand method of referring individually to each separate value falling within the range. Unless otherwise indicated herein, each separate value, as well as intermediate ranges, are incorporated into the specification as if individually recited herein. All methods described herein can be performed in any suitable order unless otherwise indicated herein or otherwise clearly contraindicated by the text.

As used herein, the prefix “micro” refers to an element having dimensions in the range of approximately 1 micron (μm) to approximately 5 millimeter (mm) As used herein, the term “approximately” when used in connection with a value refers to within 10% of the stated value. As used herein the term “and/or” means one of or both of an entity. Thus, A and/or B means A or B, or both A and B.

In a number of representative embodiments, devices hereof are microdevices and have no dimension greater than 5 mm, no greater than 1 mm, no greater than 500 μm, no greater than 300 μm, or no greater than 287 μm. However, devices hereof may be larger (for example, on the scale of centimeters).

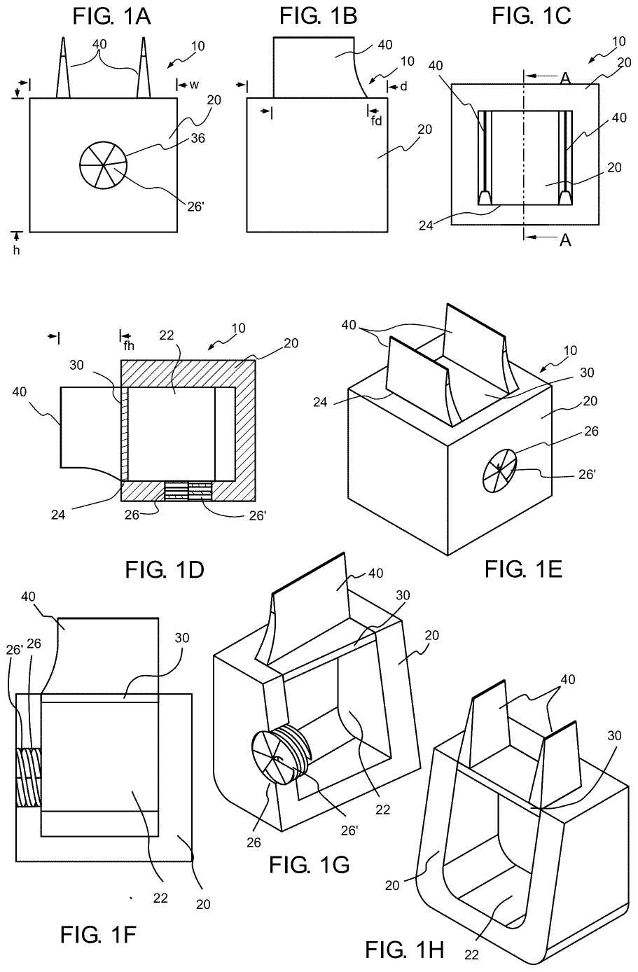

FIGS. 1A through 1G illustrate a representative embodiment of a device or microdevice 10 hereof that can create streaming flow (and thereby reactive thrust) in a liquid when activated by acoustic energy. Device 10 includes a body or resonator body 20 having a of cavity 22 (resonator cavity) therein. A diaphragm 30 extends across or over an opening 24 in body 20 which connects to cavity 22. One or more extending member or fins 40 extend from diaphragm 30. In devices hereof, thrust direction is determined by the orientation of extending members or fins 40 regardless of the direction of the applied acoustic energy (acoustic wave direction).

Representative embodiments of 3D microdevices such as device 10 hereof were fabricated using a two-photon polymerization method, which is a 3D printing technique that uses a focused laser to create structures with high precision and resolution (as known in the 3D printing arts). In a number of embodiments, devices 10 were 3D designed with Shapr3D software (a 3D modeling tool available from Shapr3D of Budapest, Hungary) and printed with IP-PDMS material (a 3D printing polydimethylsiloxane photoresin) with a Nanoscribe® 3D printer (solid scan of laser power 110 mW available from Nanoscribe Inc., Woburn, Massachusetts U.S.A.). A scanning speed of 10 mm/s was used. Resonator body 20, diaphragm 30, and extending member or fins 40 were formed integrally via 3D printing. To form a hermetic acoustic resonator after fabrication, a round developing hole 26 was left behind in resonator body 20 for later sealing (via a sealing cap 26′). In that regard, fillets were added to form cap 26′, thereby sealing hole 26 and hermetic sealing the entire cavity structure. After printing and developing, resonator body 20 was dried in air for removal of liquid content. Liquid uncured resin was added to sealing hole 26 and cured with UV lamp for sealing of hermetic chamber or cavity 22. After fabrication, device 10 and other devices hereof were placed in water tank for observation under acoustic actuation via an immersion acoustic actuator.

In various applications, the ultrasound energy generator or actuator hereof would be acoustically coupled to the liquid in which a device hereof is immersed. For example, when devices hereof are immersed with blood in the body, the ultrasound energy generator or actuator (such as an ultrasound probe) may be placed in contact with the skin of the body. An acoustically coupling gel may be placed between the ultrasound energy generator or actuator and the skin.

The dimensions of cavity 22 may be methodically selected/designed to resonate at a particular frequency such that the oscillation amplitude of diaphragm 30 is, for example, controllably tuned and maximized. In a number of embodiments, body 20 was formed to have a width w of approximately 220 μm, a depth d of approximately 210 μm, and a variable height h (see FIGS. 1A and 1B) to tune resonance as discussed further below. The cavity wall thickness was approximately 30 μm. The diaphragm and fin depth (designated fd in FIG. 1B) was approximately 140 μm. Fin or extending member heights/lengths (that is, the length of extension away from diaphragm 30 (designated fh of FIG. 1D) of 0 to approximately 270 μm were studied in representative experiments hereof. In a number of embodiments hereof, the height of extending members 40 is desirably in the range of approximately 80 μm to 130 μm, or in the range of approximately 90 μm to 115 μm. In view of the present specification and well-known engineering principles, and considering the requirements of a particular manufacture material and use, one skilled in the art can readily determine various dimensions of the components of microdevices hereof to achieve a desired range of thrust or microstreaming flow.

In a number of studied embodiments hereof, the printed PDMS material used in forming the devices hereof had a Young's modulus of 15 MPa. Regular PDMS has a Young's modulus in the range of approximately 1 to 3 MPa. In determining suitable materials for use herein (particularly materials having a higher Young's modulus range), an ANSYS (engineering simulation software available from Ansys, Inc. of Canonsburg, Pennsylvania, U.S.A.) analysis or experimental method as described herein may be carried out to determine propulsion performance. In general, in comparing materials, a softer material may provide better performance through higher oscillation amplitude. However, if oscillation is smaller in amplitude (for example, as a result of a higher young's modulus), a longer fin structure may be used to improve performance.

Under acoustic input, the oscillation of diaphragm 30 is transmitted to and amplified in extending member(s) or fin(s) 40, which are attached to diaphragm 30 (at lateral side edges thereof in the illustrated embodiment). Such a design of microdevices 10 hereof solves the problems of poor longevity (associated with bubble-based devices) and the ultra-flexibility requirement (associated with sharp-edge-based devices) since air in cavity 22 is encapsulated by diaphragm 30 and large amplitude in fin oscillation is generated without using ultra flexible fins. The frequency tuneability of devices 10 is retained upon attachment of extending members/fins 40. Moreover, as described above, thrust direction is determined by the orientation of extending members or fins 40 regardless of the applied acoustic wave direction.

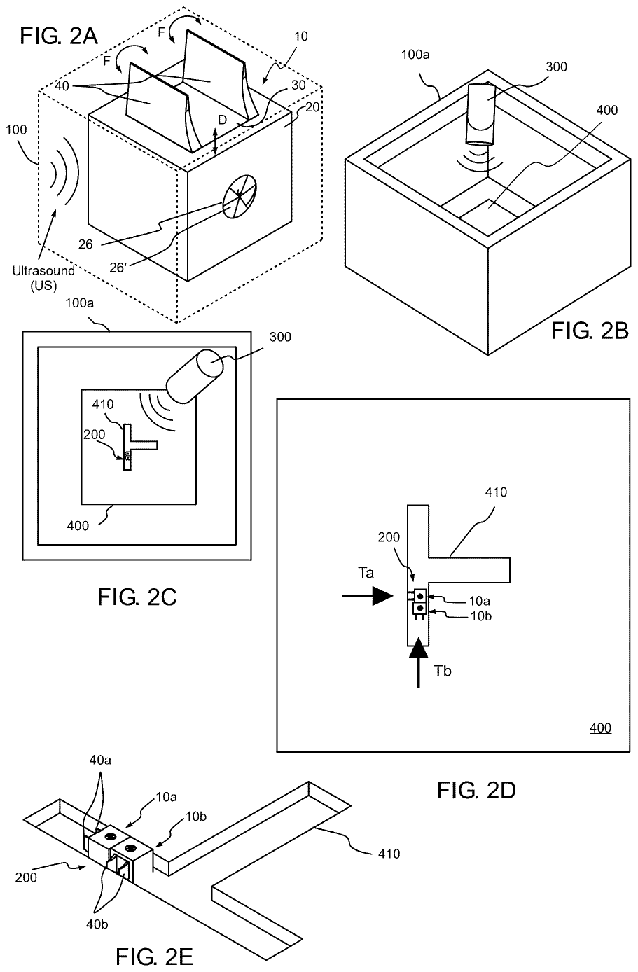

FIG. 2A illustrates a device 10 hereof positioned within a volume of water 100 (illustrated in broken lines), wherein applied ultrasound (US) resonates in cavity 22 of device 10, oscillates diaphragm 30, generates large movements in both fins 40 of device 10, and generates streaming flow in the liquid and, thereby, strong propulsion. As illustrated in FIGS. 2C through 2E, multiple devices 10a and 10b hereof, having different resonator dimensions and thereby different, tuned resonator frequencies, can be assembled into an assembly or system 200 to control a direction of motion of assembly 200 in multiple dimensions (either 2D or 3D). In that regard, one may steer assembly 200 in various directions by matching the acoustic frequency applied via immersion acoustic actuator 300 to resonant frequency of one of differently oriented devices 10 of assembly 200. Assembly 200, including integrated devices 10a and 10b, were fabricated from PDMS using a two-photon polymerization 3-D printer (Nanoscribe®) as described above, and tested in water tank 100a with excitation by ultrasound acoustic actuator 300 as illustrated in FIGS. 2C through 2E.

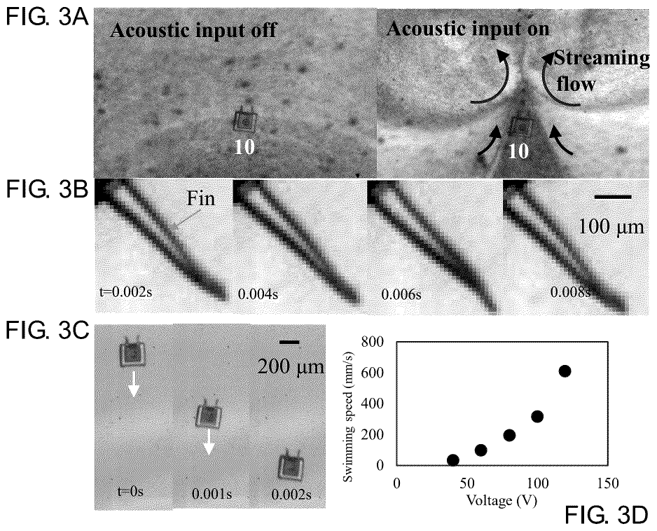

In other studies as illustrated in FIG. 3A, strong streaming flows were generated by an anchored device 10 hereof under acoustic excitation (30 kHz), which were visualized using seeded particles. Fin undulation, responsible for streaming flow generation, is clearly observed as illustrated in FIG. 3B. The streaming flow generates a reactionary force (propulsion), which propels an unanchored device 10 as illustrated in FIG. 3C. As illustrated in FIG. 3D, the speed at which device 10 is propelled quadratically increases as the input voltage to ultrasound actuator 300 increases, reaching up to ˜0.6 m/s (which is an order of magnitude faster than achieved bubble-based microswimmers).

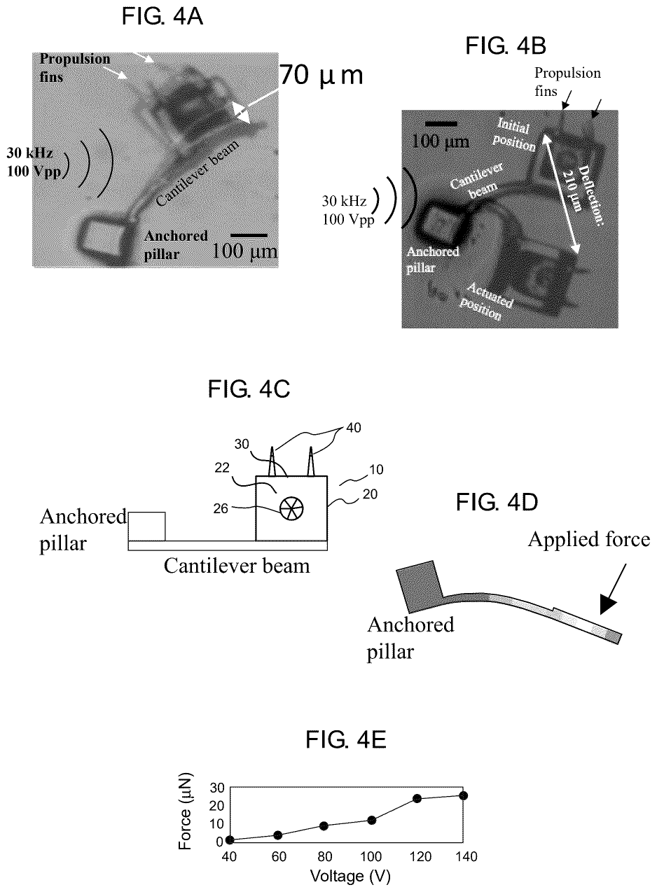

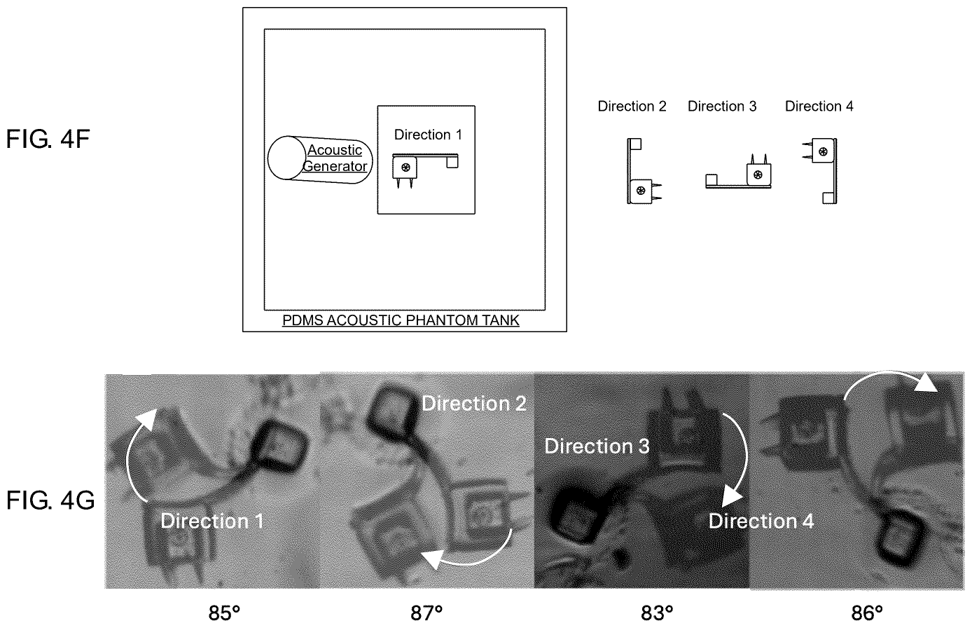

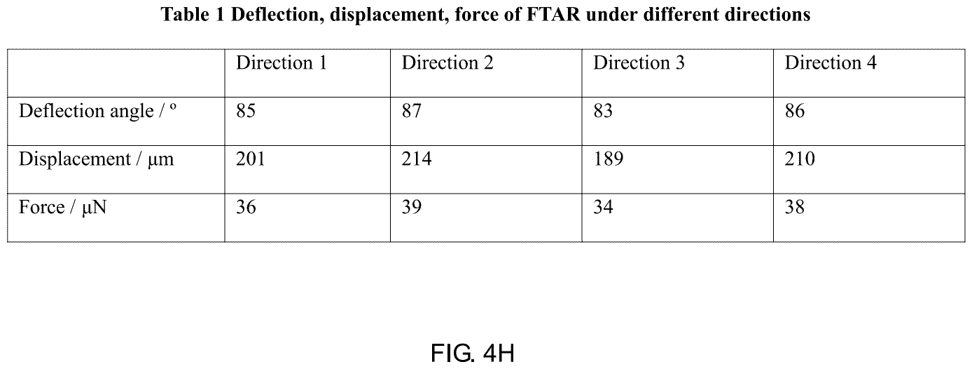

The propulsion force was measured in the μN range by ANSYS simulations using measured cantilever beam deflections (see FIGS. 4A through 4E) using the fin thruster on acoustic resonator devices hereof. To study the magnitude of force a device hereof can provide, a 500 μm long cantilever beam was printed together with device 10. When, for example, a 30 kHz 100 Vₚₚ sinusoidal wave is applied to a piezo ultrasonic actuator 300, 210 μm deflection was observed on the cantilever beam as a result of the propulsion force arising from device 10 (see FIG. 4B). This result, together with material properties of IP-PDMS was entered into ANSYS for analysis of the magnitude of force which was applied to the beam. Results showed that 20 μN was applied. Compared to force from a micro bubble swimmer of 0.8 μN, that force is much larger. By using a maximum velocity of 0.6 cm/s with the Stokes law, drag force on device 10 is estimated to be 1 μN. This result indicates that the force is adequate for generating a speed up to 0.6 m/s. FIG. 4E illustrates the influence of voltage applied to actuator or generator 300 upon force generated by device 10.

Further investigations were conducted using the experimental setup illustrated in FIG. 4F. Previous studies on microswimmers often relied on transmitting acoustic waves through glass plates or oscillations created within a water tank, wherein external mechanical systems affect the results of the studies. Eliminating the influence of external mechanical systems is an important task for improving experimental accuracy. In a number of studies, a piezo bender actuator (which is a two-layer piezoelectric transducer used in ultrasound applications to create a larger displacement than a single piezo element) was replaced with an acoustic beam. An acoustic beam is a directed sound wave which may be created by a system of sound sources. Use of generator of an acoustic beam is closer to the manner in which, for example, in vivo applications would be accomplished. In that regard, an acoustic beam is more likely to be directed at a target location. An acrylic tank was initially used. However, because acrylic is a hard material that reflects acoustic waves, interference between reflected and incident waves could affect experimental results. Indeed, experimental results indicated that the location of the acoustic actuator in the acrylic tank significantly influenced the oscillation amplitude of the devices hereof.

To address that problem, further studies were conducted in a tank made from phantom tissue material fabricated with polydimethylsiloxane (PDMS) at a 20:1 ratio of PDMS to curing agent. That material was chosen because its acoustic impedance closely matches that of water or human body tissue, reducing reflections at the tank-water interface. The incident acoustic waves dissipate instead of reflecting, effectively eliminating interference from reflected waves.

Studies were conducted to evaluate the directional dependency of the acoustic beam actuation on device 10 hereof. A cantilever beam design was once again employed to measure the propulsion effect of device 10 as, for example, illustrated in FIG. 4F. In those studies, the acoustic beam was fixed, and the substrate with device 10 was rotated to test various beam directions as illustrated in FIG. 4F. Under the same frequency and amplitude (30 kHz, 140 Vₚₚ), similar deflection angles were achieved on the same cantilever beam device setup regardless of the incoming acoustic beam direction. See, for example, FIG. 4G. Deflection angle, displacement of the tip of the device, and force estimated from ANSYS simulation is summarized in Table 1 of FIG. 4H. Beam direction played only a small role in determining the device propulsion strength. These results indicate that the devices hereof mitigate directional dependency, which is important in practical applications. For example, when used in vivo, wherein acoustic beams may originate from various directions, a device hereof may be actuated in a desired direction regardless of the acoustic beam direction.

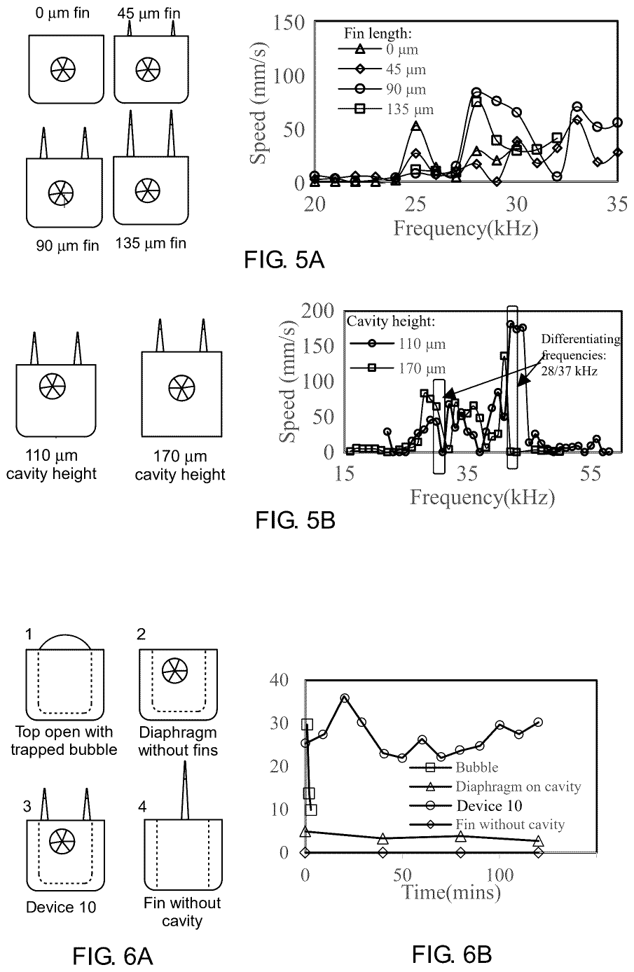

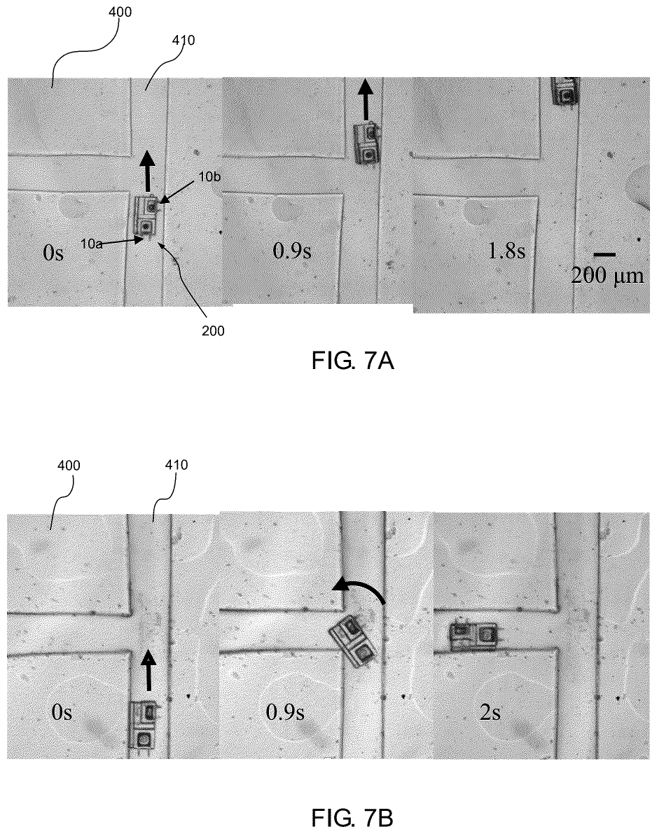

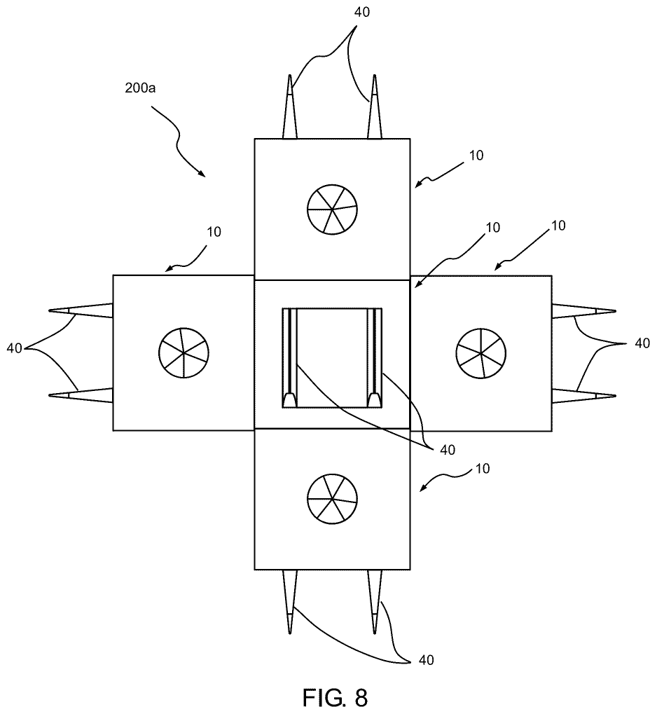

The effect of fin length and cavity height on swimming speed was investigated in the frequency domain. As illustrated in FIG. 5A, fin lengths of 0, 45, 90, and 135 μm were studied in frequency domain. The 90-μm fin length demonstrated the fastest swimming speed. The swimming speed spectra for two cavity heights (110 and 170 μm) for devices 10a and 10b of assembly 200 were quite different, demonstrating good frequency tunability as illustrated in FIG. 5B. Subsequently, for the studies of assembly 200 of FIGS. 7A and 7B, two frequencies of 28 and 37 kHz were selected where swimming speeds of devices 10a and 10b were significantly different. The effectiveness of devices 10 (FIG. 6A, panel 2) hereof was compared with three other configurations: (1) bubble trapped in the cavity without diaphragm (FIG. 6A, panel 1); (2) cavity plus diaphragm without fins (FIG. 6A, panel 2); and a fin on solid body without cavity (FIG. 6A, panel 4). Among them, the device 10 outperforms all in swimming speed as well as longevity (FIG. 6B). Over a 100-min testing period, the swimming speed of device 10 was maintained high while the swimming speed of the bubble in cavity device decreased significantly within a few minutes (likely as a result of bubble dissolution). The device with a fin and with no cavity did not generate noticeable propulsion. Embodiments with a single fin and a cavity were shown to generate propulsion, but providing multiple fins facilitates stronger propulsion and control over steering in embodiments for microswimming.

In the studies of FIGS. 7A and 7B, it was demonstrated that an assembly including integrated devices 10a and 10b hereof could navigate a T-junction in microchannel 410 formed in a substrate 400 (see FIGS. 2C, 7A, and 7B). Throughout the straight navigation (FIG. 7A), only device 10a (170 μm cavity height) was activated with 28 kHz acoustic input, while device 10b (110 μm cavity height) was activated with 37 kHz acoustic input to turn left (in the orientation of the figure) at the T-junction of microchannel 410 (FIG. 7B).

FIG. 8 illustrates an embodiment of a microswimming assembly or system 200a hereof for controlled propulsion and steering in three directions or dimensions. Referring to the orientation of the drawing on the page, multiple devices 10 may be integrated in assembly 200a to provide propulsion in an upward, downward, left, right, out of the page, and into the page directions (as well as directions therebetween). A device 10 on the underside of assembly 200a to provide propulsion in a direction out of the page is not shown in FIG. 8 but assembly 200a may be generally symmetrically formed. Many other combinations of devices 10 and/or similar devices hereof are possible in forming assemblies hereof. Volumes of spacer materials can be included in assemblies or systems hereof which are not a component of resonant, microstreaming devices as described herein to achieve a determined shape and controlled motion for a particular assembly or system.

In summary, one or more dimensions of cavity(ies) 22 of device(s) 10 and assemblies (200) hereof are readily determined (and manufactured) to resonate at particular frequencies such that the oscillation amplitude of diaphragm(s) 30 is maximized at “tuned” frequencies. Under acoustic input, the oscillation of diaphragm 30 is transmitted to and amplified in extending members or fins 40 attached to diaphragm 30 (for example, on the lateral or side edges thereof). Oscillation of extending member or fins 40 creates strong streaming flow and in turn reactionary propelling forces. The design of devices 10 and assemblies 200 hereof solves both issues of poor longevity and ultra-flexibility requirement occurring with other thrusters powered by acoustic excitations. Unlike the case of bubble-based thrusters, the air in cavity 22 is encapsulated by diaphragm 30, and large amplitude oscillation of extending members or fins 40 oscillation is generated without requiring ultra flexible fins. The frequency tuneability is retained upon assembly of multiple devices 10 into an microswimmer assembly hereof. As described above, multiple devices 10, with different resonator dimensions and different fin orientations, can be assembled into assemblies 200 hereof to enable steering of those microswimmer assemblies 200 in various directions by matching the acoustic frequency to the resonant frequency of each device 10 of assembly 200.

Devices 10 and assemblies 200 hereof provide at least the following unique advantages: (1) strong propulsion (for example, demonstrating up to at least approximate 0.6 m/s swimming speed); (2) longevity due to encapsulation of cavity resonator, (3) no requirement for ultra flexibility in the device material; and (4) good frequency tunability allowing for activating only desired devices/thrusters among a plurality devices/thrusters by matching the resonant frequencies (for example, for multi-direction steering of a microswimmer assembly including a plurality of differently oriented devices hereof). By selectively activating one or more microdevices in an untethered microswimming robotic assembly, remotely controllable 2D or 3D steered navigations are achievable.

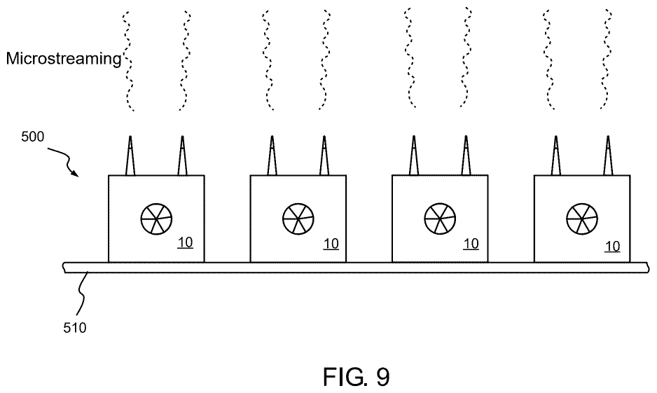

Although the devices and assemblies hereof have been discussed primarily in connection with microswimming applications, one skilled in the art will appreciate that the devices hereof can be used in connection with any application in which it is desirable to induce microstreaming and/or the reactive forces which result from induce microstreaming. Such applications, for example, include enhancement of mixing/mass transfer and flow generation in many types of microfluidic applications. FIG. 9 illustrates schematically an embodiment of a system 500 herein including a surface 510 upon which a plurality of devices 10 hereof are immobilized to induce microstreaming in a liquid (represented via idealized wavy, broken lines). Devices 10 may be tuned as described herein to determined resonance frequencies to control which devices are resonated.

The foregoing description and accompanying drawings set forth a number of representative embodiments at the present time. Various modifications, additions and alternative designs will, of course, become apparent to those skilled in the art in light of the foregoing teachings without departing from the scope hereof, which is indicated by the following claims rather than by the foregoing description. All changes and variations that fall within the meaning and range of equivalency of the claims are to be embraced within their scope.

What is claimed is:

1. A device, comprising a body, the body having a cavity therein, a diaphragm separating the cavity from an environment surrounding the device to enclose a gas within the cavity, and one or more extending members attached to and extending outwardly from a surface of the diaphragm, the cavity resonating upon application of ultrasound energy thereto to cause movement in the diaphragm and in the one or more extending members.

2. The device of claim 1 comprising a plurality of the extending members.

3. The device of claim 2 comprising at least two of the extending members.

4. The device of claim 2 wherein the dimensions of the cavity are selected to control a resonance frequency of the cavity.

5. The device of claim 4 wherein the body has no dimension greater than 5 mm.

6. The device of claim 4 wherein the body has no dimension greater than 1 mm.

7. The device of claim 4 wherein the body has no dimension greater than 270 μm.

8. The device of claim 6 wherein each of the plurality of extending members has a height of no greater than 270 μm.

9. The device of claim 6 wherein each of the plurality of extending members has a height in the range of 80 μm to 130 μm.

10. An assembly, comprising: a plurality of devices which are attached, each of the devices, comprising a body, the body having a cavity therein, a diaphragm separating the cavity from an environment surrounding the device to enclose a gas within the cavity, and one or more extending members attached to and extending outwardly from a surface of the diaphragm, the cavity resonating upon application of ultrasound energy thereto to cause movement in the diaphragm and in the one or more extending members, each of two or more of the plurality of devices being attached in different orientations and having different resonance frequencies to achieve controlled steered motion via streaming flow and propulsion in a liquid in which the assembly is immersed via control of applied ultrasound energy.

11. The assembly of claim 10 wherein each of the plurality of devices comprises a plurality of the extending members.

12. The assembly of claim 11 wherein each of the plurality of devices comprises two of the extending members.

13. The assembly of claim 10 wherein the dimensions of the cavity are selected to control a resonance frequency of the cavity.

14. The assembly of claim 13 wherein the body has no dimension greater than 5 mm.

15. The assembly of claim 13 wherein the body has no dimension greater than 1 mm.

16. The assembly of claim 13 wherein the body has no dimension greater than 270 μm.

17. The assembly of claim 15 wherein each of the one or more extending members has a height of no greater than 270 μm.

18. The assembly of claim 15 wherein each of the one or more extending members has a height in the range of 80 μm to 130 μm.

19. A method of generating streaming, comprising:
providing one or more devices, each of the one or more devices comprising a body, the body having a cavity therein, a diaphragm separating the cavity from an environment surrounding the device to enclose a gas within the cavity, and one or more extending members attached to and extending outwardly from a surface of the diaphragm, the cavity resonating upon application of ultrasound energy thereto to cause movement in the diaphragm and in the one or more extending members,
immersing the one or more devices in a liquid, and
applying ultrasound energy to cause resonance in the cavity of the one or more devices.

20. The method of claim 19 wherein generating streaming is used to provide motion to the one or more of the devices or to a substrate to which the devices are attached.

21. The method of claim 19 wherein an ultrasound energy generator is acoustically coupled to the liquid to apply the ultrasound energy.
